(19) United States
(12) Patent Application Publication
(10) Pub. No.: US 2022/0278157 A1
(43) Pub. Date: Sep. 1, 2022

(54) SOLID-STATE IMAGING DEVICE AND METHOD OF PRODUCING THE SAME

(71) Applicant: TOPPAN Inc., Tokyo (JP)

(72) Inventors: Kazuhiro TAJIMA, Taito-ku (JP); Kenta ARIYAMA, Taito-ku (JP)

(73) Assignee: TOPPAN Inc., Tokyo (JP)

(21) Appl. No.: 17/749,808

(22) Filed: May 20, 2022

Related U.S. Application Data
(63) Continuation of application No. PCT/JP2020/043045, filed on Nov. 18, 2020.

(30) Foreign Application Priority Data
Nov. 20, 2019 (JP) 2019-209618

(51) Int. Cl. H01L 27/146

(52) U.S. Cl. CPC H01L 27/14627; H01L 27/14685; H01L 27/14621

(57) ABSTRACT

A solid-state imaging device including a semiconductor substrate including photoelectric conversion elements formed in first and second directions, color filters of respective colors formed on the semiconductor substrate, and lens elements formed on the color filters. Each of the lens elements includes a transmission portion and a microlens portion, the microlens portion has a height greater than a height of the transmission portion, the transmission portion is formed between the microlens portion and the color filter such that light from the microlens portion is transmitted toward the photoelectric conversion element, and the lens elements are formed such that the microlens portions have gaps between the microlens portions adjacent in the first and second directions, and a third direction intersecting the first and second directions at 45° , and that the transmission portions are formed connected to each other with no gaps therebetween in the first, second and third directions.

### CROSS-REFERENCE TO RELATED APPLICATIONS

The present application is a continuation of International Application No. PCT/JP2020/043045, filed Nov. 18, 2020, which is based upon and claims the benefits of priority to Japanese Application No. 2019-209618, filed Nov. 20, 2019.The entire contents of all of the above applications are incorporated herein by reference.

### BACKGROUND OF THE INVENTION

### FIELD OF THE INVENTION

The present invention relates to solid-state imaging devices such as CCDs or CMOSs using photoelectric conversion elements such as photodiodes, and methods of producing the same.

### DISCUSSION OF THE BACKGROUND

There are known solid-state imaging devices such as CCDs (charged coupled devices) or CMOSs (complementary metal-oxide semiconductors) such as one shown in FIG. 5, using photoelectric conversion elements such as photodiodes (e.g., see JP 2008-270679 A).

FIG. 5 shows a solid-state imaging device 110 including a semiconductor substrate 111, a plurality of photoelectric conversion elements 112 provided inside the semiconductor substrate 111, and color filters 113A to 113C of respective colors provided on the semiconductor substrate 111 aligned with the respective photoelectric conversion elements 112. There are also provided lens elements 114 covering the respective color filters 113A to 113C. The lens elements 114 each include a flat portion 114a on which a columnar portion 114b having substantially a prismatic shape is formed aligned with the corresponding photoelectric conversion element 112 and the corresponding one of the color filters 113A to 113C. Furthermore, microlens portions 114c each having substantially an elliptical shape are formed on the respective columnar portions 114b.

In such a solid-state imaging device 110, light incident on the microlens portions 114c of the lens elements 114 is ensured to pass through the columnar portions 114b and the flat portions 114a, and reach the photoelectric conversion elements 112 via the color filters 113A to 113C.

### SUMMARY OF THE INVENTION

According to an aspect of the present invention, a solid-state imaging device includes a semiconductor substrate including photoelectric conversion elements two-dimensionally formed in a first direction and a second direction orthogonal to the first direction, color filters of respective colors formed on the semiconductor substrate such that the color filters are aligned with the respective photoelectric conversion elements, and lens elements formed on the color filters. Each of the lens elements includes a transmission portion and a microlens portion which protrudes from the transmission portion and is aligned with the photoelectric conversion element, the microlens portion has a height greater than a height of the transmission portion, and includes a same material as the transmission portion, the transmission portion is formed between the microlens portion and the color filter such that light from the microlens portion is transmitted toward the photoelectric conversion element, and the lens elements are formed such that the microlens portions have gaps between the microlens portions adjacent in the first direction, the second direction, and a third direction intersecting the first direction and the second direction at an angle of 45° , and that the transmission portions are formed connected to each other with no gaps therebetween in the first direction, the second direction, and the third direction.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic cross-sectional view illustrating a principal part of a solid-state imaging device according to a main embodiment of the present invention.

FIG. 2 is a plan view illustrating the solid-state imaging device as viewed in the direction of the arrow II shown in FIG. 1.

FIGS. 3A-3E are a set of diagrams illustrating a method of producing a solid-state imaging device according to a main embodiment of the present invention.

FIG. 4 is a diagram illustrating height and width of an arc.

FIG. 5 is a schematic diagram illustrating a principal part of an example of a solid-state imaging device based on the conventional art.

### DESCRIPTION OF THE EMBODIMENTS

The embodiments will now be described with reference to the accompanying drawings, wherein like reference numerals designate corresponding or identical elements throughout the various drawings.

With reference to the drawings, some embodiments of a solid-state imaging device and a method of producing the same according to the present invention will be described. However, the present invention should not be construed as being limited to only the embodiments described below based on the drawings.

### (Main Embodiments)

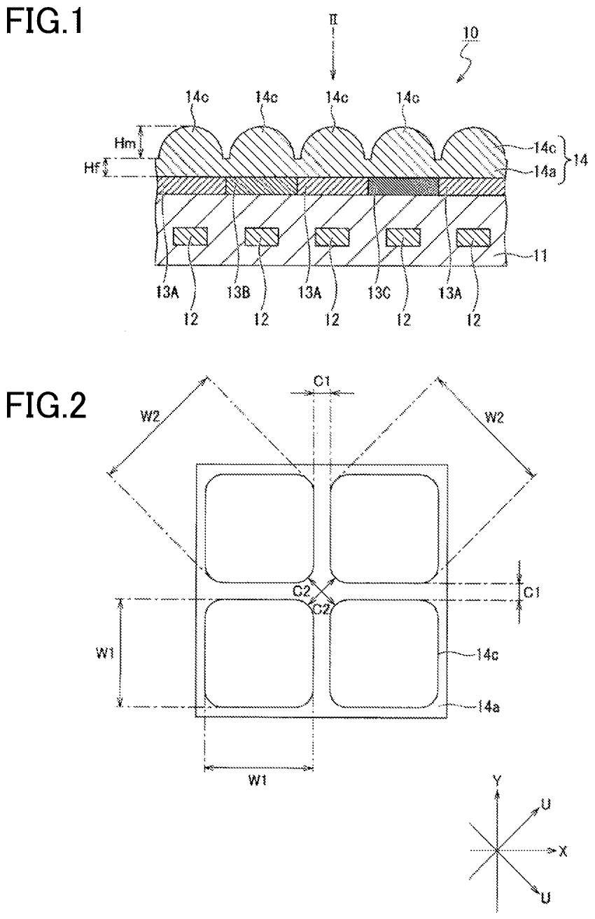

Referring to FIGS. 1 to 4, main embodiments of a solid-state imaging device and a method of producing the same according to the present invention will be described.

As shown in FIGS. 1 and 2, a plurality of photoelectric conversion elements 12 such as photodiodes are formed and two-dimensionally arranged inside a semiconductor substrate 11 in an X direction as a first direction and a Y direction as a second direction orthogonal to the X direction, in plan view in the direction of the arrow II shown in FIG. 1. In other words, in the semiconductor substrate 11, the plurality of photoelectric conversion elements 12 are two-dimensionally arranged being aligned with respective pixels. The photoelectric conversion elements 12 have a function of converting light into an electrical signal.

For the purpose of protecting and flattening a surface (light incident surface) of the semiconductor substrate 11 in which the photoelectric conversion elements 12 are formed, a protective film is typically formed on an outermost surface of the semiconductor substrate 11. The semiconductor substrate 11 is made of a material that can transmit visible light and withstand temperatures of at least around 300° C. Examples of such a material may include Si-containing materials, including Si, oxides such as SiO₂, nitrides such as SiN, and mixtures thereof.

It should be noted that surfaces of the photoelectric conversion elements 12 are located at a level in the range of, for example, 0.5 μm or more and 1.0μm or less from the surface of the semiconductor substrate 11. On the semiconductor substrate 11, a plurality of color filters 13A to 13C of respective colors are arranged being aligned with the respective photoelectric conversion elements 12. The color filters 13A to 13C are arrayed in a predetermined pattern to color-separate the incident light into corresponding colors. The color filters 13A to 13C are arrayed based on a Bayer layout, which is a regular pattern set in advance, according to the positions of the pixels so as to be aligned with the plurality of photoelectric conversion elements 12. It should be noted that the color filters 13A to 13C are not necessarily limited to being arrayed according to a Bayer layout, but may be arrayed according to other layouts.

The color filters 13A to 13C each contain a pigment (colorant) of a predetermined color and a thermosetting component and/or a photo-curable component. As the colorant, for example, the color filter 13A may contain a green pigment (G), the color filter 13B may contain a blue pigment (B), and the color filter 13C may contain a red pigment (R).

It should be noted that the color filters 13A to 13C are not limited to use three colors RGB, but may use colors obtained by combining cyan, magenta and yellow. Also, the color filters 13A to 13C may be provided with near infrared cut filters or pass filters, or the like. Furthermore, in part of the layout, the color filters 13A to 13C may include transparent elements with controlled refractive indices.

The color filters 13A to 13C may each have a width in the range of, for example, 3.9 μm or more and 4.7 μm or less. Also, the color filters 13A to 13C may each have a thickness in the range of, for example, 0.5 μm or more and 1.0 μm or less.

The color filters 13A to 13C are provided thereon with lens elements 14 covering the respective color filters 13A to 13C. In other words, the color filters 13A to 13C are provided at a level between the semiconductor substrate 11 and the lens elements 14.

The lens elements 14 respectively include microlens portions 14c, each having a projected hemispherical shape, aligned with the respective photoelectric conversion elements 12. Furthermore, the lens elements 14 respectively include flat portions 14a as transmission portions at a level between the color filters 13A to 13C and the microlens portions 14c to transmit light from the microlens portions 14c toward the photoelectric conversion elements 12.

As shown in FIG. 1, the lens elements 14 are designed so that the microlens portions 14c have a height Hm greater than a thickness (height) Hf of the flat portions 14a (Hm>Hf). The thickness Hf herein refers to the length of a perpendicular from the interface between each flat portion 14a and the corresponding microlens portion 14c to the interface between the flat portion 14a and the corresponding one of the color filters 13A to 13C. Also, the height Hm refers to the length of a perpendicular from the peak position of each microlens portion 14c to the interface between the microlens portion 14c and the corresponding flat portion 14a. It should be noted that, if the flat portions 14a and the microlens portions 14c are made of the same material, “the interface between each flat portion 14a and the corresponding microlens portion 14c” refers to an interface virtually provided between each flat portion 14a and the corresponding microlens portion 14c.

The height Hm is preferred to be 1.4 μm or more and 1.5 μm or less. This is because, if the height Hm is in the above range, sensitivity to incident light guided to the photoelectric conversion elements 12 can be further enhanced. The lens elements 14 are preferred to have a uniform height Hm and a uniform thickness Hf; however, they may vary while being produced. Therefore, when calculating the height Hm and the thickness Hf of the lens elements 14, it is preferred that several arbitrary portions (e.g., ten portions) are measured and averaged.

As shown in FIG. 2, the direction intersecting the X direction and the Y direction at 45° on the same plane is referred to as a U direction that is a third direction. In the layout of the lens elements 14, gaps Cl and C2 are formed between the microlens portions 14cadjacent in the X, Y and U directions.

The gap C1 between the microlens portions 14c adjacent in the X and Y directions is designed to be smaller (in size) than the gap C2 between the microlens portions 14c adjacent in the U direction (C1<C2). The gaps C1 and C2 herein each refer to a length that is a minimum distance between adjacent microlens portions 14c.

The gap C1 is preferred to have a size of 0.1 μm or more and 0.5 μm or less. The gap C2 is preferred to have a size of 1.2 μm or more and 1.8 μm or less. Also, the difference between the gaps C1 and C2 (C2-C1) is preferred to be 1.5 μm or less, and more preferred to be 1.2 μm or more and 1.4 μm or less. This is because, if the gaps C1 and C2 are in the above ranges, sensitivity to incident light guided to the photoelectric conversion elements 12 can be further enhanced.

In the layout of the lens elements 14, each microlens portion 14c is designed to have a width W1 in the X and Y directions, which is smaller (in size) than a width W2 thereof in the U direction (W1<W2). The widths W1 and W2 herein refer to widths in the related directions in the interface plane between each microlens portion 14c and the corresponding flat portion 14a. If the width W1 is smaller than the width W2, the amount of incident light guided to the photoelectric conversion elements 12 can be further increased.

The width W1 is preferred to have a size of 3.8 μm or more and 4.2 μm or less. The width W2 is preferred to have a size of 4.2 μm or more and 4.8 μm or less. Also, the difference between the widths W1 and W2 (W2-W1) is preferred to be 1 μm or less, and more preferred to be 0.4 μm or more and 0.6 μm or less. This is because, if the widths W1 and W2 are in the above ranges, the amount of incident light guided to the photoelectric conversion elements 12 can be further increased. In a cross section of the microlens portion 14c taken along the X direction, parallel to the thickness direction thereof in each lens element 14, the arc length of the semicircular contour is referred to as R1, and in a cross section of the microlens portion 14c taken along the Y direction, parallel to the thickness direction thereof, the arc length of the semicircular contour is also referred to as R1. Similarly, in a cross section of the microlens portion 14c taken along the U direction, parallel to the thickness direction thereof, the arc length of the semicircular contour is referred to as R2. Each microlens element 14 is designed so that at least either one of the arc lengths R1 is smaller (in size) than the arc length R2 (R1<R2).

Specifically, at least one of the arc lengths RI of the semicircular contours in cross sections of the microlens portion 14c taken along the X and Y directions, parallel to the thickness direction thereof, is designed to be smaller (in size) than the arc length R2 of the semicircular contour in a cross section thereof taken along the U direction (R1<R2).

The arc length R1 is preferred to have a size of 2.0 μm or more and 2.2 μm or less. The arc length R2 is preferred to have a size of 2.3 μm or more and 2.6 μm or less. Also, the difference between the arc lengths R1 and R2 (R2-R1) is preferred to be 1μm or less, and more preferred to be 0.2 μm or more and 0.5 μm or less. This is because, if the arc lengths R1 and R2 are in the above ranges, incidence of flare light guided to the photoelectric conversion elements 12 can be further minimized.

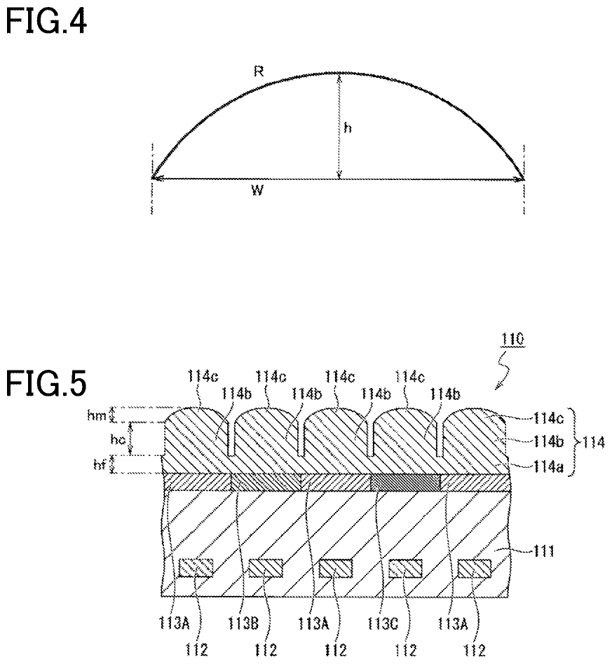

As shown in FIG. 4, the arc (semicircular contour) length (length of arc) R can be calculated based on the following Formula (1), where h indicates height of arc, and W indicates width of arc.

R={W/2)²+h²}/2h (1)

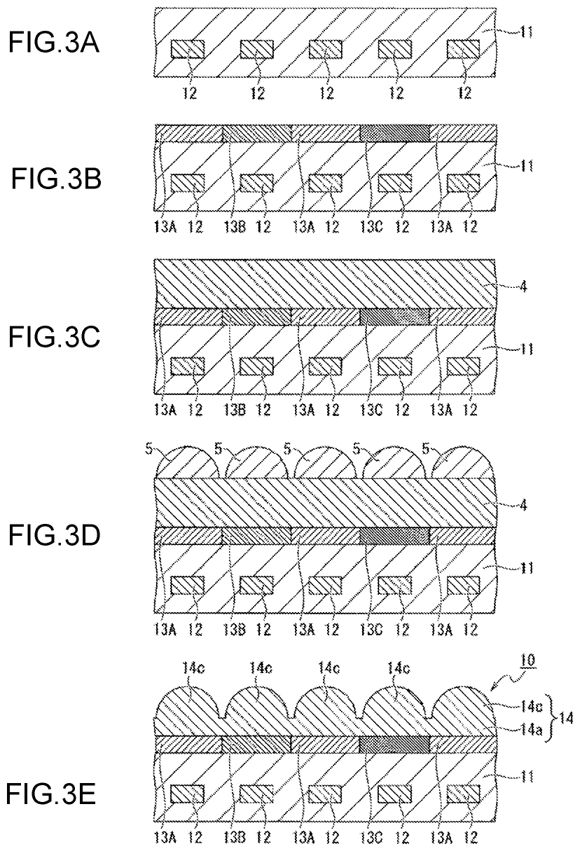

Referring to FIGS. 3A-3E, a method of producing the solid-state imaging device according to the present embodiment will be described. First, color filters 13A to 13C are provided on a semiconductor substrate 11 including photoelectric conversion elements 12 (FIG. 3A) using a known means, so that the color filters 13A to 13C are aligned with the respective photoelectric conversion elements 12 (color filter providing step: FIG. 3B).

Subsequently, a transparent layer 4 is provided on the color filters 13A to 13C to cover them (transparent layer providing step: FIG. 3C). The transparent layer 4 can be provided using a method in which a transparent resin such as an acrylic resin is applied to the color filters and cured with heat, light, or the like, or a method in which a transparent compound such as an oxide, nitride, or the like is deposited on the color filters using vapor deposition, sputtering, CVD, or the like, or other methods.

Next, matrices 5 each having a hemispherical shape corresponding to the shape of a microlens portion 14c are provided using a heat flow method on the surface of the transparent layer 4 facing away from the surface provided with the color filters 13A to 13C, so that the matrices 5 are aligned with the microlens portions 14c (matrix providing step: FIG. 3D). In other words, the matrices 5 are provided on the transparent layer 4 so as to be aligned with the respective color filters 13A to 13C and the respective photoelectric conversion elements 12.

Then, using the matrices 5 as a mask, dry etching is performed so that the shapes of the matrices 5 are transferred to the transparent layer 4, while controlling etching conditions. As a result of this, lens elements 14 are provided in each of which a flat portion 14a and a microlens portion 14c described above are formed in the transparent layer 4 (lens element forming step: FIG. 3E).

In other words, the transparent layer 4 is formed so that the gaps C1 and C2 are provided between the microlens portions 14c adjacent in the X, Y and U directions. The transparent layer 4 is formed so that the flat portions 14a are connected to each other with no gaps therebetween in the X, Y and U directions. Furthermore, the transparent layer 4 is formed so that the height Hm of the microlens portions 14c will be greater than the thickness Hf of the flat portions 14a. Through these steps, a solid-state imaging device 10 can be produced.

In other words, in the present embodiment, a transparent layer 4 is etched as follows to form lens elements 14 in which the microlens portions 14c and the flat portions 14a are made of the same material.

(1) The gaps C1 and C2 are formed between the microlens portions 14c adjacent in the X, Y and U directions of the lens elements 14.

(2) The flat portions 14a are formed connected to each other with no gaps therebetween in the X, Y and U directions of the lens elements 14.

(3) The transmission portions positioned at a level between the color filters 13A to 13C and the microlens portions 14c of the lens elements 14 are formed of only flat portions 14a lower than the microlens portions 14c.

As shown in FIG. 5, the microlens portions 114c of the lens elements 114 according to the conventional art have a small height hm, but have a long focal length. Therefore, the height of the transmission portions, which is the sum of the height hf of the flat portions 114a and the height hc of the columnar portions 114b (hf+hc), is required to be large (hf+hc>hm) and accordingly the lens elements 114 have a large thickness (hf+hc+hm).

In this regard, in the present embodiment, the gaps C1 and C2 formed between the microlens portions 14c of the lens elements 14 can reduce the arc lengths R1 and R2 of the microlens portions 14c and reduce the difference between the arc lengths R1 in the X and Y directions and the arc length R2 in the U direction (R2-R1).

Therefore, in the present embodiment, the microlens portions 14 can have a shorter focal length, and the transmission portions of the lens elements 14 can be formed of only the flat portions 14a having the height Hf smaller than the height Hm of the microlens portions 14c to reduce the thickness of the lens elements 14 (Hm+Hf).

Accordingly, the solid-state imaging device 10 and the method of producing the same according to the present embodiment can easily achieve downsizing and thus can cope with further downsizing (thinning) strongly required in recent years.

Furthermore, since the microlens portions 14c of the lens elements 14 have a shorter focal length, incident light can be narrowly focused and the amount of light guided to the photoelectric conversion elements 12 can be increased.

In addition, since the arc lengths R1 and R2 of the microlens portions 14c of the lens elements 14 can be reduced, incidence of flare light on the photoelectric conversion elements 12 can be minimized.

Furthermore, since the microlens portions 14c and the flat portions 14a are made of the same material in the lens elements 14, no interface or no refractive index difference occurs between the microlens portions 14c and the flat portions 14a. Therefore, incident light can be reliably guided to the photoelectric conversion elements 12 to significantly minimize light loss. Furthermore, the lens elements 14 can be formed using etching. Therefore, when forming the lens elements 14, the size of the gaps C1 and C2 between adjacent microlens portions 14c can be more finely controlled than when forming the lens elements on the flat portions making use of surface tension in a heat flow method. Thus, by increasing the area of each microlens portion 14c on the flat portion 14a as much as possible, the amount of light guided to the photoelectric conversion elements 12 can be easily increased as much as possible.

Specifically, the solid-state imaging device 10 according to the present embodiment having the technical characteristics as described above can easily eliminate the trade-off relationship between sensitivity characteristics and incidence of flare light, which has been an issue for the solid-state imaging devices of the conventional art. This point is briefly described below.

Of the lenses provided to the solid-state imaging devices of the conventional art, so-called flow lenses each occupy only a small area in one pixel but have high lens surface curvature, in general. Therefore, flow lenses typically have characteristics that they can sufficiently minimize incidence of flare light, although they lead to low sensitivity.

Also, of the lenses provided to the solid-state imaging devices of the conventional art, so-called etched lenses each occupy a large area in one pixel but have low lens surface curvature, in general. Therefore, etched lenses typically have characteristics that they lead to high sensitivity, although they suffer from incidence of flare light to an extent that cannot be neglected.

Thus, there has been a trade-off relationship between sensitivity characteristics and incidence of flare light in the solid-state imaging devices of the conventional art. In this regard, the solid-state imaging device 10 according to the present invention can balance improvement of sensitivity characteristics with minimization of flare light.

(Other Embodiments)

In the embodiment described above, the semiconductor substrate 11 may be provided with a flattening underlayer on the surface thereof to protect and flatten the surface. The flattening underlayer can reduce asperities on the upper surface of the semiconductor substrate 11 due to formation of the photoelectric conversion elements 12 therein, and can improve adhesion of the materials of the color filters 13A to 13C.

The flattening underlayer can be made of one or more resins. Examples of these resins may include acrylic resins, epoxy resins, polyimide resins, phenol novolak resins, polyester resins, urethane resins, melamine resins, urea resins, and styrene resins. Without being limited to these resins, any material can be used for the flattening underlayer as long as the material transmits visible light in a wavelength range of 400 nm to 700 nm and does not hinder pattern formation or adhesion of the color filters 13A to 13C.

Furthermore, the flattening underlayer is preferred to be made of a resin not affecting the spectral characteristics of the color filters 13A to 13C. For example, the flattening underlayer is preferred to be formed so that it has a transmittance of 90% or more to visible light in a wavelength range of 400 nm to 700 nm. From the perspective of preventing color mixture, the flattening underlayer is preferred to have a smaller thickness. The flattening underlayer may have a thickness, for example, in the range of 0.5 μm or more and 1.0 μm or less. In the embodiment described above, the color filters 13A to 13C may be provided with a flattening overlayer on the surfaces thereof to flatten the surfaces. The flattening overlayer can be made of one or more resins. Examples of these resins may include acrylic resins, epoxy resins, polyimide resins, phenol novolak resins, polyester resins, urethane resins, melamine resins, urea resins, and styrene resins. The flattening overlayer may be integrated with the lens elements 14. From the perspective of preventing color mixture, the flattening overlayer is preferred to have a smaller thickness. The flattening overlayer may have a thickness, for example, in the range of 0.5 μm or more and 1.0 μm or less.

Furthermore, the above embodiment has been described for the case, as shown in FIG. 2, in which C1 in the X direction is the same as C1 in the Y direction; however, the present invention should not be construed as being limited to this. Cl in the X direction and C1 in the Y direction may be different from each other. Even when C1 in the X direction and C1 in the Y direction are different from each other, advantageous effects similar to those of the present invention described above can be achieved.

Furthermore, the above embodiment has been described for the case in which the arc length R1 of the semicircular contour in a cross section taken along the X direction is the same as the arc length R1 of the semicircular contour in a cross section taken along the Y direction; however, the present invention should not be construed as being limited to this. The arc length RI of the semicircular contour in a cross section taken along the X direction may be different from the arc length R1 of the semicircular contour in a cross section taken along the Y direction. Even when the arc length R1 of the semicircular contour in a cross section taken along the X direction is different from the arc length R1 of the semicircular contour in a cross section taken along the Y direction, advantageous effects similar to those of the present invention described above can be achieved.

The present application addresses the following. In the solid-state imaging device 110 of the conventional art, the microlens portions 114c of the lens elements 114 each have a substantially elliptical shape with a relatively large curvature radius and therefore have a long focal length. As a measure for this, the solid-state imaging device 110 is designed to secure a distance to the photoelectric conversion elements 112 via the columnar portions 114b. For this reason, the solid-state imaging device 110 has a relatively large size (thickness), and thus it has been difficult to achieve further downsizing (thinning) strongly required in recent years.

For the reasons stated above, the present invention has an aspect to provide a solid-state imaging device and a method of producing the same, which can easily achieve downsizing.

A solid-state imaging device according to an aspect of the present invention includes a semiconductor substrate in which a plurality of photoelectric conversion elements are two-dimensionally arranged in a first direction and a second direction orthogonal to the first direction; a plurality of color filters of respective colors arranged on the semiconductor substrate so as to be aligned with the respective photoelectric conversion elements; and lens elements arranged on the color filters so as to cover the color filters, characterized in that the lens elements include a plurality of microlens portions protruded and aligned with the respective photoelectric conversion elements, and transmission portions positioned at a level between the color filters and the microlens portions to transmit light from the microlens portions toward the photoelectric conversion elements; the microlens portions and the transmission portions of the lens elements are made of the same material; the transmission portions of the lens elements are formed connected to each other with no gaps therebetween in the first direction, the second direction, and a third direction intersecting the first direction and the second direction at an angle of 45° ; gaps are formed between the microlens portions adjacent in the first direction, the second direction, and the third direction; and the microlens portions of the lens elements have a height that is greater than a height of the transmission portions.

Furthermore, a method of producing a solid-state imaging device according to an aspect of the present invention is characterized in that, in a method of producing the solid-state imaging device described above, the method includes steps of providing the color filters on the semiconductor substrate so as to be aligned with the respective photoelectric conversion elements of the semiconductor substrate; providing a transparent layer on the color filters so as to cover the color filters; providing matrices, each having a shape corresponding to a respective microlens portion, on the transparent layer so as to be aligned with the respective microlens portions; and providing the lens elements by forming the microlens portions and the transmission portions in the transparent layer by etching the transparent layer using the matrices as a mask to transfer shapes of the matrices to the transparent layer, with the gaps being formed between the microlens portions adjacent in the first direction, the second direction, and the third direction, with the transmission portions being connected to each other with no gaps therebetween in the first direction, the second direction, and the third direction, and with a height of the microlens portions being made greater than a height of the transmission portions.

The solid-state imaging device and the method of producing the same according to an aspect of the present invention can easily achieve downsizing and thus can cope with further downsizing (thinning) strongly required in recent years. Industrial Applicability

The solid-state imaging device and the method of producing the same can be applied to various optical devices such as digital cameras, and therefore can be used extremely beneficially in industry.

Reference Signs List

10 Solid-state imaging device

11 Semiconductor substrate

12 Photoelectric conversion element

13A to 13C Color filter

14 Lens element

14a Flat portion

14c Microlens portion

Obviously, numerous modifications and variations of the present invention are possible in light of the above teachings. It is therefore to be understood that within the scope of the appended claims, the invention may be practiced otherwise than as specifically described herein.

What is claimed is:

1. A solid-state imaging device, comprising
a semiconductor substrate including a plurality of photoelectric conversion elements two-dimensionally formed in a first direction and a second direction orthogonal to the first direction;
a plurality of color filters of respective colors formed on the semiconductor substrate such that the color filters are aligned with the respective photoelectric conversion elements; and
a plurality of lens elements formed on the color filters,
wherein each of the lens elements includes a transmission portion and a microlens portion which protrudes from the transmission portion and is aligned with the photoelectric conversion element,
the microlens portion has a height greater than a height of the transmission portion, and includes a same material as the transmission portion,
the transmission portion is formed between the microlens portion and the color filter such that light from the microlens portion is transmitted toward the photoelectric conversion element, and
the lens elements are formed such that the microlens portions have gaps between the microlens portions adjacent in the first direction, the second direction, and a third direction intersecting the first direction and the second direction at an angle of 45° , and that the transmission portions are formed connected to each other with no gaps therebetween in the first direction, the second direction, and the third direction.

2. The solid-state imaging device according to claim 1, wherein the microlens portions adjacent in the first direction and the second direction have a gap of 0.1 μm-0.5 μm, and the microlens portions adjacent in the third direction have a gap of 0.1 μm-2.0 μm.

3. The solid-state imaging device according to claim 1, wherein in each of the lens elements, an arc length of a semicircular contour in a cross section of the microlens portion taken along the first direction, parallel to a thickness direction thereof, is different from an arc length of a semicircular contour in a cross section of the microlens portion taken along the third direction, parallel to the thickness direction thereof, by 1.0 μm or less.

4. The solid-state imaging device according to claim 2, wherein in each of the lens elements, an arc length of a semicircular contour in a cross section of the microlens portion taken along the first direction, parallel to a thickness direction thereof, is different from an arc length of a semicircular contour in a cross section of the microlens portion taken along the third direction, parallel to the thickness direction thereof, by 1.0 μm or less.

5. The solid-state imaging device according to claim 1, wherein in each of the lens elements, an arc length of a semicircular contour in a cross section of the microlens portion taken along the first direction, parallel to the thickness direction thereof, and an arc length of a semicircular contour in a cross section of the microlens portion taken along the second direction, parallel to the thickness direction thereof, are each 2.0 μm — 2.2 μm, and in each of the lens elements, an arc length of a semicircular contour in a cross section of the microlens portion taken along the third direction, parallel to the thickness direction thereof is 2.3 μm — 2.6 μm.

6. The solid-state imaging device according to claim 2, wherein in each of the lens elements, an arc length of a semicircular contour in a cross section of the microlens portion taken along the first direction, parallel to the thickness direction thereof, and an arc length of a semicircular contour in a cross section of the microlens portion taken along the second direction, parallel to the thickness direction thereof, are each 2.0 μm — 2.2 μm, and
in each of the lens elements, an arc length of a semicircular contour in a cross section of the microlens portion taken along the third direction, parallel to the thickness direction thereof is 2.3 μm — 2.6 μm.

7. The solid-state imaging device according to claim 3, wherein in each of the lens elements, an arc length of a semicircular contour in a cross section of the microlens portion taken along the first direction, parallel to the thickness direction thereof, and an arc length of a semicircular contour in a cross section of the microlens portion taken along the second direction, parallel to the thickness direction thereof, are each 2.0 μm — 2.2 μm, and
in each of the lens elements, an arc length of a semicircular contour in a cross section of the microlens portion taken along the third direction, parallel to the thickness direction thereof is 2.3 μm — 2.6 μm.

8. A method of producing the solid-state imaging device according to claim 1, comprising:
forming the color filters on the semiconductor substrate such that the color filters are aligned with the respective photoelectric conversion elements of the semiconductor substrate;
forming a transparent layer on the color filters;
forming matrices on the transparent layer such that each of the matrices has a shape and a position corresponding to the microlens portion; and
forming the microlens portions and the transmission portions in the transparent layer by etching the transparent layer using the matrices as a mask such that the shape of each of the matrices is transferred to the transparent layer.

9. The method according to claim 8, wherein the matrices are formed on the transparent layer by a heat flow method.
